(19) United States
(12) Patent Application Publication
(10) Pub. No.: US 2026/0231703 A1
(43) Pub. Date: Aug. 6, 2026

(54) SUBSTRATE PROCESSING METHOD

(71) Applicant: ASM IP Holding B.V., Almere (NL)

(72) Inventor: Wataru Adachi, Kawasaki-shi (JP)

(21) Appl. No.: 19/180,592

(22) Filed: Apr. 16, 2025

Related U.S. Application Data
(60) Provisional application No. 63/636,555, filed on Apr. 19, 2024.

(51) Int. Cl. H10P 14/60; C23C 16/44; H10P 14/692

(52) U.S. Cl. CPC H10P 14/6339; C23C 16/4408; H10P 14/665; H10P 14/6922

(57) ABSTRACT

A method of forming a film on a substrate comprises providing the substrate to a reaction chamber and forming the film on the substrate by repeating a cycle comprising: supplying a first silicon source comprising an acetoxy group and supplying a hydrogen source while applying a power to the reaction chamber from a power source, wherein the hydrogen source reacts with the acetoxy group of the first silicon source to form an adsorption site reactive to the acetoxy group, wherein the film formed on the substrate comprises a silicon oxycarbonate (SiOC).

### CROSS-REFERENCE TO RELATED APPLICATIONS

This application claims priority to U.S. Provisional Patent Application Ser. No. 63/636,555 filed Apr. 19, 2024 titled SUBSTRATE PROCESSING METHOD, the disclosure of which is hereby incorporated by reference in its entirety.

### FIELD OF INVENTION

The disclosure relates to a method of processing a substrate, more particularly, to a method of forming an oxide film on the substrate without supplying an oxygen source.

### BACKGROUND OF THE DISCLOSURE

As a line width of a semiconductor device shrinks, an RC delay (Resistance-Capacitance delay) of an insulation layer of the device causes a slow response time of the device. Therefore, a material with low dielectric constant (a low-k material hereinafter) is introduced. A SiOC film is usually used as a low-k material. The SiOC film is formed at relatively low temperature to reduce a thermal budget in fabricating the device. To that end, a Plasma Enhanced Atomic Layer Deposition (PEALD) method is employed. In the PEALD method, a reactant gas is activated by a power and reacts with the source gas to form a film at low temperature. In order to form the SiOC film by the PEALD method, a silicon source and an oxygen source activated by a power are supplied sequentially and intermittently to form the film. The activated oxygen source, however, causes damage to the sublayers (e.g., oxidation of a conductive layer), resulting in low performance of the device.

Therefore, it is required to form the SiOC film, without damaging the sublayers at low temperature.

### SUMMARY OF THE DISCLOSURE

The disclosure introduces a method of forming a film on a substrate, more particularly, a SiOC film on a substrate without causing a damage to sublayers.

In one or more embodiments, the method of forming the film on a substrate comprising a patterned structure may comprise: providing the substrate in a reaction chamber, and forming the film on the substrate by repeating a cycle comprising: supplying a first silicon source comprising an acetoxy group, and supplying a hydrogen source, wherein the hydrogen source may react with the acetoxy group of the first silicon source to form an adsorption site reactive to the acetoxy group, wherein the film formed on the substrate may comprise a silicon oxycarbonate (SiOC).

In one or more embodiments, the first silicon source may comprise an acetoxysilane.

In one or more embodiments, the first silicon source may comprise at least one of a triacetoxymethylsilane [(CH₃CO₂)₃SiCH₃], triacetoxyethylsilane [(CH₃CO₂)₃SiCH₂CH₃], diacetoxydimethylsilane [(CH₃CO₂)₂Si(CH₃)₂], triacetoxy(vinyl)silane [(CH₃CO₂)₃SiCH═CH₂], 1,3-diacetoxy-1,3-dimethyl-1,3-disiletane [C₈H₁₁O₄Si₂], or a mixture thereof.

In one or more embodiments, the hydrogen source may comprise at least one of atomic hydrogen, and dihydrogen, or a mixture thereof.

In one or more embodiments, the adsorption site may comprise a hydroxyl group (i.e., —OH).

In one or more embodiments, a power may be applied to the reaction chamber while supplying the hydrogen source, wherein the power may be applied to activate the hydrogen source with an intensity of between about 100 W and about 300 W at a frequency of between about 10 MHz and about 100 MHz.

In one or more embodiments, the power may be applied to the reaction chamber in pulse.

In one or more embodiments, the method may be performed at between about 100° C. and about 500° C.

In one or more embodiments, a film growth rate of the film may be about 0.025 Å/cycle or greater.

In one or more embodiments, purging the reaction chamber after supplying the first silicon source may be performed by evacuating the reaction chamber.

In one or more embodiments, the method may further comprise supplying a second silicon source comprising at least one of an alkyl group and an alkylamine group, an alkyl group and a silyl amine group, an alkyl group and an alkoxy silane group, an alkoxy silyl group and alkane group, and an alkoxy group and silinane group, an alkyl group and a siletane group, or a mixture thereof before or after supplying the first silicon source.

In one or more embodiments, the second silicon source may comprise at least one of N,N-diethyl-2,4,6,8-tetramethyl-cycleotetrasiloxan-2-amine [C₈H₂₅NO₄Si₄], (dimethylamino)trimethylsilane [(CH₃)₂NSi(CH₃)₃], bis(dimethylamino)dimethylsilane [(CH₃)₂N]₂Si(CH₃)₂, ethoxy(trimethyl)silane [C₂H₅OSi(CH₃)₃], diethoxy(dimethyl)silane [(C₂H₅O)₂Si(CH₃)₂], triethoxymethylsilane [(C₂H₅O)₃SiCH₃], bis(triethoxysilyl)methane [(C₂H₅O)₃SiCH₂Si(OC₂H₅)₃], bis(triethoxysilyl)ethane [(C₂H₅O)₃SiCH₂CH₂Si(OC₂H₅)₃], 4,4,6,6-tetramethyl-3,7-dioxa-4,6-disilanonane [(C₂H₅O)(CH₃)₂SiCH₂Si(CH₃)₂(OC₂H₅)], 1,3-diethoxy-1,3-dimethyl-1,3-disiletane [C₈H₂₀O₂Si₂], 1,3,5-triethoxy-1,3,5-trimethyl-1,3,5-trisilinane [C₁₂H₃₀O₃Si₃], 1,1,3,3,5,5-hexaethoxy-1,3,5-trisilinane [C₁₅H₃₆O₆Si₃], 1,3-diacetoxy-1,3-dimethyl-1,3-disiletane [C₈H₁₆O₄Si₂], or a mixture thereof.

In one or more embodiments, purging at least one of after supplying the first silicon source and after supplying the second silicon source may be performed by evacuating the reaction chamber.

This summary is provided to introduce a selection of concepts in a simplified form. These concepts are described in further detail in the detailed description of example embodiments of the disclosure below. This summary is not intended to identify key features or essential features of the claimed subject matter, nor is it intended to be used to limit the scope of the claimed subject matter.

### BRIEF DESCRIPTION OF THE DRAWING FIGURES

FIG. 1 illustrates a method of forming a film according to an embodiment of the disclosure.

FIG. 2 illustrates a timing graph of one embodiment of the method of FIG. 1.

FIGS. 3A to 3C illustrate a reaction mechanism of the method of FIGS. 1 and 2.

FIG. 4 illustrates a method of forming a film according to another embodiment of the disclosure.

FIG. 5 illustrates a timing graph of one embodiment of the method of FIG. 4.

FIGS. 6A to 6D illustrate a reaction mechanism of the method of FIGS. 4 and 5.

FIG. 7 shows a TEM (Transmission Electron Microscope) image of SiOC film formed on the patterned structure by using the method of the disclosure.

FIG. 8 illustrates a film growth rate of a SiOC film according to a ratio of a hydrogen source to a whole gas supplied during the power is applied.

FIG. 9 illustrates an exemplary apparatus to perform the method according to the present disclosure.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION OF EXEMPLARY EMBODIMENTS

Although certain embodiments and examples are disclosed below, it will be understood by those in the art that the invention extends beyond the specifically disclosed embodiments and/or uses of the invention and obvious modifications and equivalents thereof. Thus, it is intended that the scope of the invention disclosed should not be limited by the particular disclosed embodiments described below.

As used herein, the term “substrate” may refer to any underlying material or materials, including any underlying material or materials that may be modified, or upon which, a device, a circuit, or a film may be formed. The “substrate” may be continuous or non-continuous; rigid or flexible; solid or porous; and combinations thereof. The substrate may be in any form, such as a powder, a plate, or a workpiece. Substrates in the form of a plate may include wafers in various shapes and sizes. Substrates may be made from semiconductor materials, including, for example, silicon, silicon germanium, silicon oxide, gallium arsenide, gallium nitride and silicon carbide.

A continuous substrate may extend beyond the bounds of a process chamber where a deposition process occurs. In some processes, the continuous substrate may move through the process chamber such that the process continues until the end of the substrate is reached. A continuous substrate may be supplied from a continuous substrate feeding system to allow for manufacture and output of the continuous substrate in any appropriate form.

The illustrations presented herein are not meant to be actual views of any particular material, structure, or device, but are merely idealized representations that are used to describe embodiments of the disclosure.

The terms ‘first’ and ‘second’ do not necessarily mean that the ‘first’ needs to come before the ‘second’. The terms ‘first’ and ‘second’ are just to distinguish the different properties between them. Therefore, the ‘second’ may come before the ‘first’ the other way around.

The particular implementations shown and described are illustrative of the invention and its best mode and are not intended to otherwise limit the scope of the aspects and implementations in any way. Indeed, for the sake of brevity, conventional manufacturing, connection, preparation, and other functional aspects of the system may not be described in detail. Furthermore, the connecting lines shown in the various figures are intended to represent exemplary functional relationships and/or physical couplings between the various elements. Many alternative or additional functional relationship or physical connections may be present in the practical system, and/or may be absent in some embodiments.

It is to be understood that the configurations and/or approaches described herein are exemplary in nature, and that these specific embodiments or examples are not to be considered in a limiting sense, because numerous variations are possible. The specific routines or methods described herein may represent one or more of any number of processing strategies. Thus, the various acts illustrated may be performed in the sequence illustrated, in other sequences, or omitted in some cases.

The subject matter of the present disclosure includes all novel and nonobvious combinations and subcombinations of the various processes, systems, and configurations, and other features, functions, acts, and/or properties disclosed herein, as well as any and all equivalents thereof.

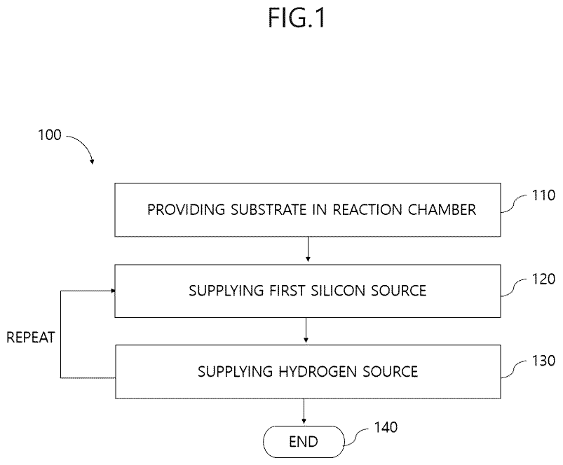

FIG. 1 illustrates a method 100 of forming a film according to an embodiment of the disclosure.

In STEP 110 of the method 100 of forming the film, a substate may be provided in a reaction chamber. The substrate may comprise a patterned structure (e.g., a gap structure).

In STEP 120, a first silicon source may be supplied to the substrate. The first silicon source may be chemisorbed on an adsorption site (e.g., —OH, a hydroxyl group) of a surface of the substrate. The first silicon source may comprise an acetoxy group. In one embodiment, the first silicon source may comprise an acetoxysilane. For instance, the first silicon source may comprise at least one of one of a triacetoxymethylsilane [(CH₃CO₂)₃SiCH₃], triacetoxyethylsilane [(CH₃CO₂)₃SiCH₂CH₃], diacetoxydimethylsilane [(CH₃CO₂)₂Si(CH₃)₂], triacetoxy(vinyl)silane [(CH₃CO₂)₃SiCH═CH₂], 1,3-diacetoxy-1,3-dimethyl-1,3-disiletane [C₈H₁₆O₄Si₂], or a mixture thereof.

In STEP 130, a hydrogen source may be supplied to the substrate. The hydrogen source may be supplied while applying a power to the reaction chamber from a power source. The power may be applied in-situ or remotely with an intensity of between about 100 W and about 300 W at a frequency of between about 10 MHz and about 100 MHz. In one embodiment of the disclosure, the power may be applied to the reaction chamber in continuous mode. In another embodiment of the disclosure, the power may be applied to the reaction chamber in pulsed mode.

The hydrogen source may comprise at least one of atomic hydrogen (H), diatomic hydrogen (H₂), or a mixture thereof. The hydrogen source may react with the acetoxy group (i.e., H₃C—C(═O)—O—) of the first silicon source to form an adsorption site reactive to the acetoxy group of the first silicon source in the subsequent cycle. The adsorption site may be a hydroxyl group (i.e., —OH). The film formed on the substrate may comprise a silicon oxycarbonate (SiOC).

The STEPs 120 and 130 may be repeated a plurality of times, comprising a cycle, until a desired thickness is achieved. Then, in STEP 140, the method 100 of forming the film may end.

In one or more embodiments, the method 100 may be performed at a temperature between about 100° C. and about 500° C.

In one or more embodiments, the method 100 may be performed at a pressure about 3 Torr or below.

In one or more embodiments, a film growth rate of the film according to the method 100 may be about 0.025 Å/cycle or greater.

In one or more embodiments of the disclosure, the method 100 may further comprise purging the reaction chamber at least one of after supplying the first silicon source (STEP 120) and after supplying the hydrogen source (STEP 130).

In one or more embodiments of the disclosure, purging the reaction chamber after supplying the first silicon source may be performed by evacuating the reaction chamber.

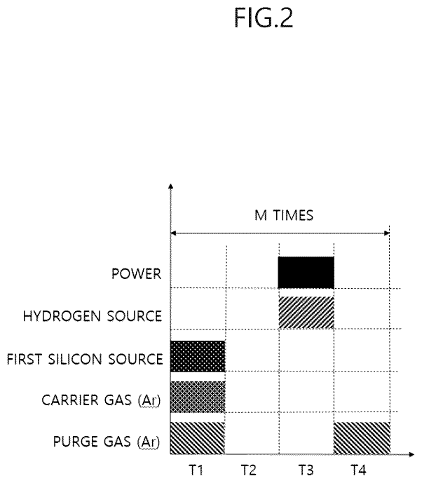

FIG. 2 illustrates a timing graph of one embodiment of the method 100 of FIG. 1.

In T1, a first silicon source may be supplied to the substrate loaded in the reaction chamber. The first silicon source may be carried to the reaction chamber by a carrier gas (e.g., Ar). A purge gas (e.g., Ar) may be further supplied to the reaction chamber. The first silicon source may be chemisorbed on the substrate.

In T2, a purge may be performed to remove a residual first silicon source from the reaction chamber. The purge in T2 may be performed by evacuating the reaction chamber. Optionally, the purge in T2 may be performed by supplying a purge gas (e.g., Ar).

In T3, a hydrogen source may be supplied to the substrate through a while a power is applied to the reaction chamber from a power source, resulting in activating the hydrogen source. The activated hydrogen may react with the first silicon source adsorbed on the substrate, resulting in forming an adsorption site (i.e., —OH, a hydroxyl group)

In T4, a purge may be performed by supplying the purge gas to remove by-products from the reaction chamber. The T1 to T4 may be repeated a plurality of times in cycle (M times) to form the film. The film may be a silicon oxycarbonate (SiOC). The method 100 in FIG. 1 and FIG. 2 may have a technical benefit of forming a SiOC film without supplying an oxygen source (i.e., oxygen radicals). Therefore, damage to the sublayers by the oxygen source may be prevented.

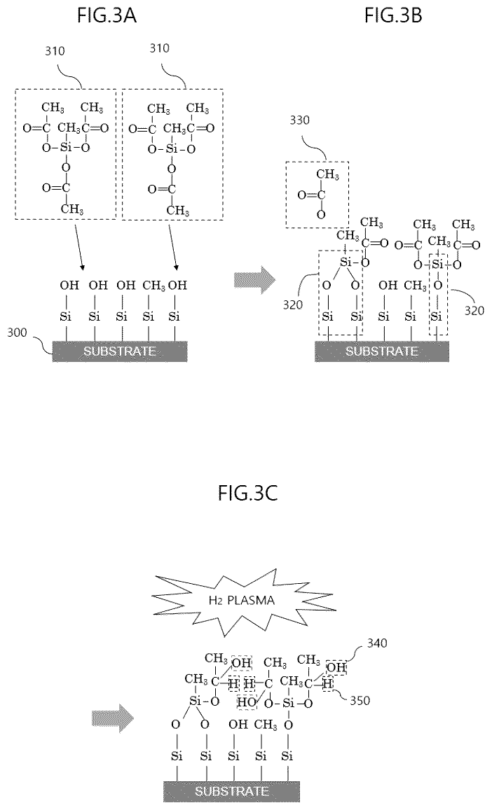

FIGS. 3A to 3C illustrate a reaction mechanism of the method 100 in FIGS. 1 and 2.

In FIG. 3A, a triacetoxymethylsilane [(CH₃CO₂)₃SiCH₃] 310 may be supplied as a first silicon source to the substrate 300. The substrate may comprise a SiOC film, for instance. The surface of the film may comprise Si-based bonding structures. For instance, the surface of the substrate may comprise —OH (hydroxyl group) and —CH₃(methyl group).

In FIG. 3B, the triaceoxymethylsilane 310 may be chemisorbed on the surface of the film. In more detail, the triacetoxymethylsilane may react with the hydroxyl group (i.e., —OH) as an adsorption site comprising the surface of the film, resulting in forming a Si—O—Si bonding structure 320 and being the acetoxy group 330 (i.e., H₃C—C(═O)—O—) removed as a by-product.

In FIG. 3C, diatomic hydrogen (H₂) as a hydrogen source may be supplied to the substrate while applying a power to the reaction chamber from a power source to generate a hydrogen plasma, resulting in forming hydrogen radicals from the hydrogen plasma.

The hydrogen radicals may react with the oxygen bonded with the carbon, resulting in forming a hydroxyl group (—OH) 340 and a hydrogen (H) 350. The hydroxyl group may act as an adsorption site for the silicon source supplied in the subsequent cycle. The carbon and the hydrogen may remain in the film, forming a SiOC film, and may lower a dielectric constant (k) of the film. Therefore, a low-k SiOC film may be formed.

FIGS. 3A to 3C may be repeated a plurality of times until a desired thickness (a target thickness) is achieved.

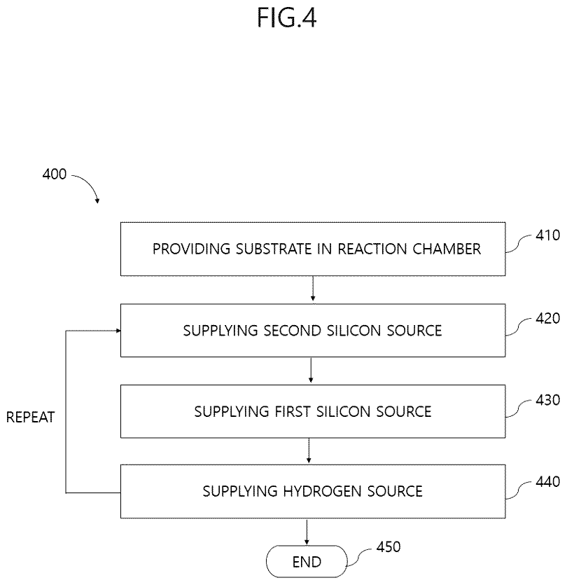

FIG. 4 illustrates a method of forming a film according to another embodiment of the disclosure.

In STEP 410 of the method 400 of forming the film, a substate may be provided in a reaction chamber. The substrate may comprise a patterned structure (e.g., a gap structure).

In STEP 420, a second silicon source may be supplied to the substrate. The second silicon source may comprise at least one of an alkyl group and an alkylamine group, an alkyl group and a silyl amine group, an alkyl group and an alkoxy silane group, an alkoxy silyl group and alkane group, and an alkoxy group and silinane group, an alkyl group and a siletane group, or a mixture thereof.

The second silicon source may comprise at least one of N,N-diethyl-2,4,6,8-tetramethyl-cycleotetrasiloxan-2-amine [C₈H₂₅NO₄Si₄], (dimethylamino)trimethylsilane [(CH₃)₂NSi(CH₃)₃], bis(dimethylamino)dimethylsilane [(CH₃)₂N]₂Si(CH₃)₂, ethoxy(trimethyl)silane [C₂H₅OSi(CH₃)₃], diethoxy(dimethyl)silane [(C₂H₅O)₂Si(CH₃)₂], triethoxymethylsilane [(C₂H₅O)₃SiCH₃], bis(triethoxysilyl)methane [(C₂H₅O)₃SiCH₂Si(OC₂H₅)₃], bis(triethoxysilyl)ethane [(C₂H₅O)₃SiCH₂CH₂Si(OC₂H₅)₃], 4,4,6,6-Tetramethyl-3,7-dioxa-4,6-disilanonane [(C₂H₅O)(CH₃)₂SiCH₂Si(CH₃)₂(OC₂H₅)], 1,3-diethoxy-1,3-dimethyl-1,3-disiletane [C₈H₂₀O₂Si₂], 1,3,5-triethoxy-1,3,5-trimethyl-1,3,5-trisilinane [C₁₂H₃₀O₃Si₃], 1,1,3,3,5,5-hexaethoxy-1,3,5-trisilinane [C₁₅H₃₆O₆Si₃], 1,3-diacetoxy-1,3-dimethyl-1,3-disiletane [C₈H₁₆O₄Si₂], or a mixture thereof.

The second silicon source may be chemisorbed on the hydroxyl group (i.e., —OH) as an adsorption site formed on the substrate via a reactive group (e.g., [CₙH₂ₙ₊₁]ₓN, alkylamine group) of the second silicon source. An alkyl group (—CₙH₂ₙ₊₁) of the second silicon source may not react with the substrate and remain in the film. The space in which the alkyl group occupies may result in a pore in the film later, lowering the dielectric constant of the film further.

In STEP 430, a first silicon source may be supplied to the substrate. The first silicon source may be chemisorbed on an adsorption site (i.e., —OH, a hydroxyl group) of a surface of the substrate. The first silicon source may comprise an acetoxy group. In one embodiment, the first silicon source may comprise an acetoxysilane. For instance, the first silicon source may comprise at least one of one of a triacetoxymethylsilane [(CH₃CO₂)₃SiCH₃], triacetoxyethylsilane [(CH₃CO₂)₃SiCH₂CH₃], diacetoxydimethylsilane [(CH₃CO₂)₂Si(CH₃)₂], triacetoxy(vinyl)silane [(CH₃CO₂)₃SiCH═CH₂], 1,3-diacetoxy-1,3-dimethyl-1,3-disiletane [C₈H₁₆O₄Si₂], or a mixture thereof.

In STEP 440, a hydrogen source may be supplied to the substrate. The hydrogen source may be supplied while applying a power to the reaction chamber from a power source. The power may be applied in-situ or remotely with an intensity of between about 100 W and about 300 W at a frequency of between about 10 MHz and about 100 MHz. In one embodiment of the disclosure, the power may be applied to the reaction chamber in continuous mode. In another embodiment of the disclosure, the power may be applied to the reaction chamber in pulsed mode.

The hydrogen source may comprise at least one of atomic hydrogen (H), diatomic hydrogen (H₂), or a mixture thereof. The hydrogen source may be activated by the applied power and may react with the acetoxy group (i.e., H₃C—C(═O)—O—) of the first silicon source to form an adsorption site reactive to the acetoxy group of the first silicon source in the subsequent cycle. The adsorption site may be a hydroxyl group (i.e., —OH). The film formed on the substrate may comprise a silicon oxycarbonate (SiOC).

Since the second silicon source may be chemisorbed on the substrate and the space which the non-reactive group (i.e., an alkyl group) occupies may result in a pore in the SiOC film, the dielectric constant of the film may be lowered further. Therefore, a low-k SiOC film may be formed.

In FIG. 4, the method 400 may not use an oxygen source. Thus, damage to sublayers (e.g., a conductive interlayer) by an oxygen plasma may be prevented. Therefore, a low electric performance of the device may be prevented accordingly.

The STEPs 420 and 440 may be repeated a plurality of times, comprising a cycle, until a target thickness is achieved. Then, in STEP 450, the method 400 of forming the film may end.

In FIG. 4, the second silicon source may be supplied, followed by supplying the first silicon source. In another embodiment, the first silicon source may be supplied, followed by supplying the second silicon source. In other words, the second silicon source may be supplied before or after supplying the first silicon source.

In one or more embodiments, the method 400 may be performed at a temperature between about 100° C. and about 500° C.

In one or more embodiments, the method of 400 may be performed at a pressure about 3 Torr or below.

In one or more embodiments, a film growth rate of the film according to the method 400 may be greater than about 0.025 Å/cycle.

In one or more embodiments of the disclosure, the method 400 may further comprise purging the reaction chamber at least one of after supplying the first silicon source (STEP 430), after supplying the second silicon source (STEP 420), and after supplying the hydrogen source (STEP 440).

In one or more embodiments of the disclosure, purging at least one of after supplying the first silicon source and after supplying the second silicon source may be performed by evacuating the reaction chamber.

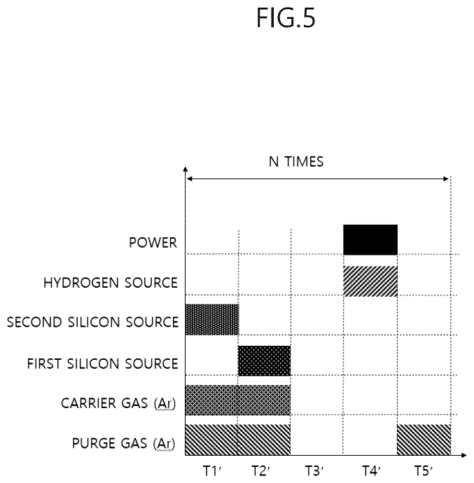

FIG. 5 illustrates a timing graph of one embodiment of the method of FIG. 4.

In T1′, a second silicon source may be supplied to the substrate loaded in the reaction chamber. The second silicon source may be carried to the reaction chamber by a carrier gas (e.g., Ar). A purge gas (e.g., Ar) may also be supplied to the reaction chamber. The second silicon source may be chemisorbed on the substrate.

In T2′, a first silicon source may be supplied to the substrate loaded in the reaction chamber. The first silicon source may be carried to the reaction chamber by a carrier gas (e.g., Ar). Optionally, a purge gas (e.g., Ar) may be further supplied to the reaction chamber. The first silicon source may be chemisorbed on the substrate.

In T3′, a purge may be performed to remove a residual first silicon source and a residual second silicon source from the reaction chamber. The purge in T3′ may be performed by evacuating the reaction chamber. Optionally, the purge gas (e.g., Ar) may be further supplied in T3′.

In T4′, a hydrogen source may be supplied to the substrate while applying a power to the reaction chamber from a power source. The activated hydrogen may react with the first silicon source adsorbed on the substrate, resulting in forming an adsorption site (i.e., —OH, a hydroxyl group). Optionally, the purge gas (e.g., Ar) may be further supplied in T4′.

In T5′, a purge may be performed by supplying the purge gas (e.g., Ar) to remove by-products from the reaction chamber. The T1′ to T5′ may be repeated a plurality of times in cycle (N times) to form the film. The film may be a silicon oxycarbonate (SiOC).

The method 400 in FIG. 4 and FIG. 5 may have a technical benefit of forming a SiOC film without supplying an oxygen source (i.e., oxygen radicals). Therefore, damage to the sublayers by the oxygen source may be prevented.

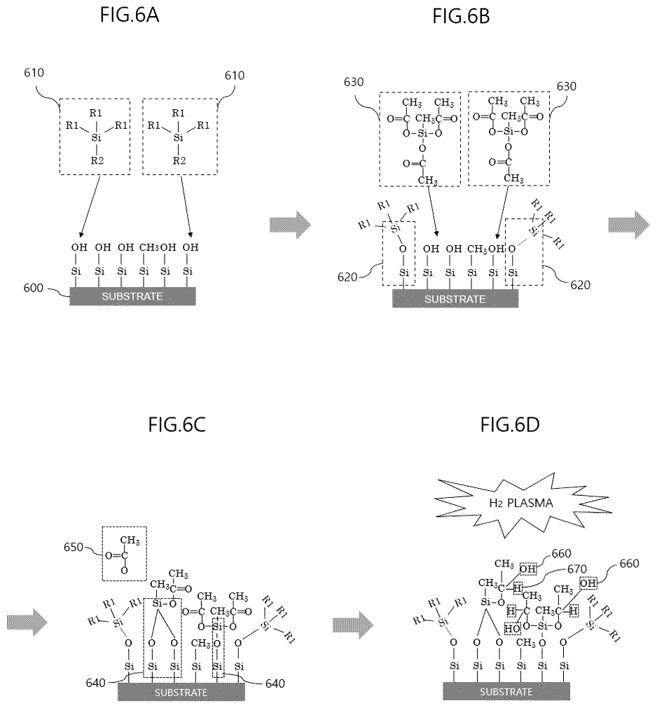

FIGS. 6A to 6D illustrate a reaction mechanism of the method 400 in FIGS. 4 and 5.

In FIG. 6A, a bis(dimethylamino)dimethylsilane([(CH₃)₂N]₂Si(CH₃)₂) 610 may be supplied as a second silicon source to the substrate 600. The second silicon source 610 may comprise an alkyl group (CₙH₂ₙ₊₁, R1) and a reactive group (alkylamine group, (CₙH₂ₙ₊₁)ₓN, R2), for instance. The substrate may comprise a SiOC film, for instance. The surface of the film may comprise Si-based bonding structures. For instance, the surface of the substrate may comprise —OH (hydroxyl group) as an adsorption site and —CH₃(methyl group).

The second silicon source 610 may react with the hydroxyl group as an adsorption site via the reactive group R2, resulting in forming a Si—O—Si bonding structure 620 as shown in FIG. 6B. An alkyl group (—CₙH₂ₙ₊₁, R1) of the second silicon source 610 may not react with the substrate and remain in the film. The space which the alkyl group occupies may result in a pore in the film later, lowering the dielectric constant of the film further.

In FIG. 6B, a triacetoxymethylsilane [(CH₃CO₂)₃SiCH₃] 630, may be supplied to the substrate as a first silicon source.

In FIG. 6C, the first silicon source 630 may react with the hydroxyl group (i.e., —OH) formed on the surface of the substrate, resulting in forming a Si—O—Si bonding structure 640 and being the acetoxy group 650 (i.e., H₃C—C(═O)—O—) removed as a by-product.

In FIG. 6D, diatomic hydrogen (H₂) as a hydrogen source may be supplied to the substrate while applying a power to the reaction chamber from a power source to generate a hydrogen plasma, resulting in forming hydrogen radicals from the hydrogen plasma.

The hydrogen radicals may react with the oxygen bonded with the carbon of the first silicon source, resulting in forming a hydroxyl group (—OH) 660 and a hydrogen (H) 670. The hydroxyl group 660 may act as an adsorption site for the first and the second silicon sources supplied in the subsequent cycle. The carbon and the hydrogen may remain in the film, forming a SiOC film, and may lower a dielectric constant (k) of the film. Therefore, along with the pore generated by the alkyl group of the second precursor, the dielectric constant (k) of the film may be even further lowered.

FIGS. 6A to 6D may be repeated a plurality of times until a desired thickness (a target thickness) is achieved.

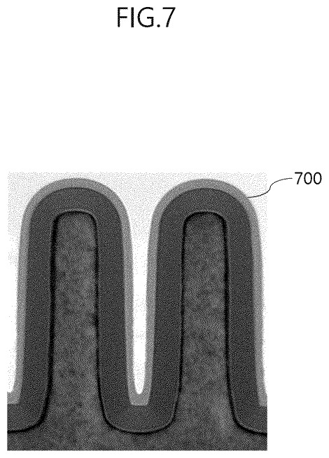

FIG. 7 shows a TEM (Transmission Electron Microscope) image of SiOC film formed on the patterned structure by the method of the disclosure. In FIG. 7, the SiOC film 700 may be formed by the method of FIGS. 1 and 2. In forming the SiOC film, a triacetoxymethylsilane may be supplied as a first silicon source, followed by supplying a hydrogen plasma. As shown in FIG. 7, the film may be formed uniformly on the patterned structure.

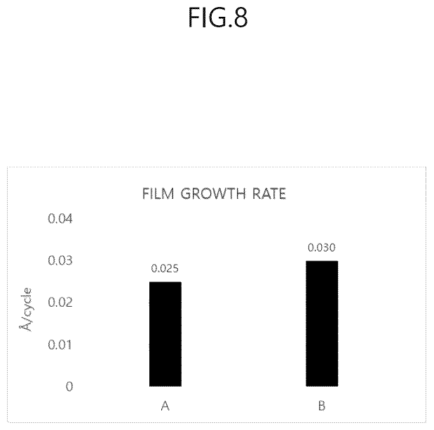

FIG. 8 illustrates a film growth rate of SiOC film according to the ratio of hydrogen source to the whole gas supplied during the power is applied.

In condition A, a hydrogen source (e.g., H₂) and a purge gas (e.g., Ar) are supplied at a flow rate of 1:1. That is, a gas flow ratio of the hydrogen source to the whole gas (e.g., H₂+Ar) is 50%.

In condition B, only hydrogen source is supplied. That is, a gas flow ratio of the hydrogen source to the whole gas is 100%.

As illustrated in FIG. 8, the film growth rate in condition A is about 0.025 Å/cycle and the film growth rate in condition B is about 0.030 Å/cycle, indicating that the film growth rate is higher in condition B than in condition A. In condition B, no blocking effect to the hydrogen radicals by Ar radicals occurs. Therefore, in condition B, more adsorption sites (i.e., —OH) may be formed and more Si—O—Si film structure may be formed accordingly.

Table 1 shows test conditions to perform the method of FIG. 1 in which a first silicon source is supplied.

TABLE 1
Test conditions to perform the method of FIG. 1

| Step | | Source feed | Purge | RF-on | Purge |
|---|---|---|---|---|---|
| Gas flow rate | Source carrier Ar | 1,000 to 3,000 | 0 | 0 | 1,000 to 3,000 |
| (sccm) | Purge Ar | 1,000 to 3,000 | 0 | 0 to 3,000 | 1,000 to 3,000 |
| | H₂ | 0 | 0 | 1,000 to 3,000 | 0 |
| Plasma | Power (W) | 0 | 0 | 100 to 300 | 0 |
| condition | Frequency (MHz) | 0 | 0 | 10 to 100 | 0 |

| | | | | |
|---|---|---|---|---|
| Step time (second) | 0.2 to 1.0 | 2.0 to 10.0 | 0.2 to 1.0 | 0.5 to 5.0 |

| | |
|---|---|
| Pressure (Torr) | ≤3 Torr |
| Process temperature (° C.) | 100° C. to 500° C. |
| Source vessel temperature (° C.) | RT(room temperature) to 100° C. |
| Silicon source | acetoxysilane |

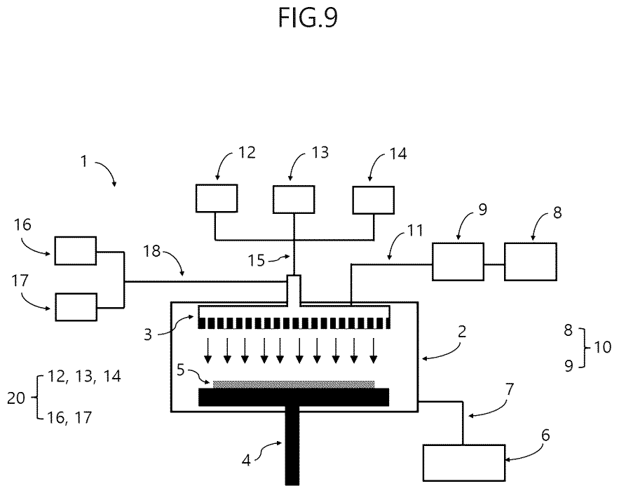

FIG. 9 illustrates one example of an apparatus to perform the method according to the present disclosure.

In FIG. 9, the apparatus 1 may comprise a reaction chamber 2, a gas supply unit 3 to supply a gas into the reaction chamber 2, a substrate supporting unit 4 supporting a substrate 5 and is disposed facing the gas supply unit 3, an exhaust unit 6 to evacuate the reaction chamber 2, an exhaust path 7 connecting the reaction chamber 2 to the exhaust unit 60, and a power supply unit 10. The power supply unit 10 may comprise a power generator (a power source) 8, a matching network 9 and a power delivery unit 11 to apply a power to the gas supply unit 3 from the power supply unit 10. The gas supply unit 3 may be a showerhead made of conductive material. The gas supply unit 3 may act as an electrode by being connected to the power supply unit 10 via the power delivery unit 11 to deliver a power to the reaction chamber 2.

The power generator 8 may generate at least one of a low frequency power (LRF) and a high frequency power (HRF). The matching network 9 may match an impedance between the power generator 8 and the reaction chamber 2. The power delivery unit 11 may deliver the power to the reaction chamber 2 from the power supply unit 10. The power delivery unit 11 may comprise a rod made of conductive material and a power deliver cable.

The apparatus 1 may further comprise a gas source unit 20 comprising a first gas source 12, a second gas source 13, a third gas source 14, a fourth gas source 16, and a fifth gas source 17.

The first gas source 12 may comprise a first silicon source comprising an acetoxysilane, for instance. The second gas source 13 may comprise a second silicon source comprising an alkyl group and an alkylamine group, for instance. The third gas source 14 may comprise an inert gas as a source carrier gas. The fourth gas source 16 may comprise a hydrogen source. The fifth gas source 17 may comprise an inert gas as a purge gas.

The first gas source 12 may supply a first silicon source gas to the reaction chamber 2 via a gas supply path 15 and the gas supply unit 3. The second gas source 13 may supply a second silicon source gas to the reaction chamber 2 via the gas supply path 15. The third gas source 14 may supply a carrier gas when the first silicon source and the second silicon gas are supplied to the reaction chamber 2 via the gas supply path 15.

The fourth gas source 16 may supply a hydrogen source gas to the reaction chamber 2 via a gas supply path 18 and the gas supply unit 3. The fifth gas source 17 may supply a purge gas to the reaction chamber 2 via the gas supply path 18.

In one or more embodiments, the substrate 5 may be processed in the reaction chamber 2 by the method comprising supplying the second silicon source gas to the substrate 5, followed by supplying the first silicon source gas to the substrate 5. After supplying the first silicon source gas, the reaction chamber 2 may be evacuated without supplying a gas.

After that, a power may be applied to the reaction chamber 2 while supplying the hydrogen source gas to the reaction chamber 2.

1. A method of forming a film on a substrate comprising a patterned structure, comprising:
providing the substrate in a reaction chamber; and
forming the film on the substrate by repeating a cycle, comprising:
supplying a first silicon source comprising an acetoxy group; and
supplying a hydrogen source, wherein the hydrogen source reacts with the acetoxy group of the first silicon source to form an adsorption site reactive to the acetoxy group, wherein the film formed on the substrate comprises a silicon oxycarbonate (SiOC).

2. The method of claim 1, wherein the first silicon source comprises an acetoxysilane.

3. The method of claim 2, wherein the first silicon source comprises at least one of a triacetoxymethylsilane [(CH₃CO₂)₃SiCH₃], triacetoxyethylsilane [(CH₃CO₂)₃SiCH₂CH₃], diacetoxydimethylsilane [(CH₃CO₂)₂Si(CH₃)₂], triacetoxy(vinyl)silane [(CH₃CO₂)₃SiCH═CH₂], 1,3-diacetoxy-1,3-dimethyl-1,3-disiletane [C₈H₁₆O₄Si₂], or a mixture thereof.

4. The method of claim 1, wherein the hydrogen source comprises at least one of atomic hydrogen, and dihydrogen, or a mixture thereof.

5. The method of claim 1, wherein the adsorption site comprises a hydroxyl group (—OH).

6. The method of claim 1, wherein a power is applied to the reaction chamber while supplying the hydrogen source, wherein the power may be applied to activate the hydrogen source with an intensity of between about 100 W and about 300 W at a frequency of between about 10 MHz and about 100 MHz.

7. The method of claim 6, wherein the power is applied in-situ or remotely.

8. The method of claim 7, wherein the power is applied to the reaction chamber in pulse.

9. The method of claim 1, wherein the method is performed at a temperature between about 100° C. and about 500° C.

10. The method of claim 1, wherein the method is performed at a pressure about 3 Torr or below.

11. The method of claim 1, wherein a film growth rate of the film is about 0.025 Å/cycle or greater.

12. The method of claim 1, further comprises purging the reaction chamber at least one of after supplying the first silicon source, and after supplying the hydrogen source.

13. The method of claim 12, wherein purging the reaction chamber after supplying the first silicon source is performed by evacuating the reaction chamber.

14. The method of claim 1, further comprises supplying a second silicon source comprising at least one of an alkyl group and an alkylamine group, an alkyl group and a silyl amine group, an alkyl group and an alkoxy silane group, an alkoxy silyl group and alkane group, and an alkoxy group and silinane group, an alkyl group and a siletane group, or a mixture thereof before or after supplying the first silicon source.

15. The method of claim 14, wherein the second silicon source comprises at least one of N,N-diethyl-2,4,6,8-tetramethyl-cycleotetrasiloxan-2-amine [C₈H₂₅NO₄Si₄], (Dimethylamino)trimethylsilane [(CH₃)₂NSi(CH₃)₃], bis(dimethylamino)dimethylsilane [(CH₃)₂N]₂Si(CH₃)₂, ethoxy(trimethyl)silane [C₂H₅OSi(CH₃)₃], diethoxy(dimethyl)silane [(C₂H₅O)₂Si(CH₃)₂], triethoxymethylsilane [(C₂H₅O)₃SiCH₃], bis(triethoxysilyl)methane [(C₂H₅O)₃SiCH₂Si(OC₂H₅)₃], bis(triethoxysilyl)ethane [(C₂H₅O)₃SiCH₂CH₂Si(OC₂H₅)₃], 4,4,6,6-tetramethyl-3,7-dioxa-4,6-disilanonane [(C₂H₅O)(CH₃)₂SiCH₂Si(CH₃)₂(OC₂H₅)], 1,3-diethoxy-1,3-dimethyl-1,3-disiletane [C₈H₂₀O₂Si₂], 1,3,5-triethoxy-1,3,5-trimethyl-1,3,5-trisilinane [C₁₂H₃₀O₃Si₃], 1,1,3,3,5,5-hexaethoxy-1,3,5-trisilinane [C₁₅H₃₆O₆Si₃], 1,3-diacetoxy-1,3-dimethyl-1,3-disiletane [C₈H₁₆O₄Si₂], or a mixture thereof.

16. The method of claim 14, wherein the film comprises a pore.

17. The method of claim 14, wherein a film growth rate of the film is greater than 0.025 Å/cycle.

18. The method of claim 14, further comprises purging the reaction chamber at least one of after supplying the first silicon source, after supplying the second silicon source, and after supplying the hydrogen source.

19. The method of claim 16, purging at least one of after supplying the first silicon source and after supplying the second silicon source is performed by evacuating the reaction chamber.

20. An apparatus performing the method of claim 1, comprising:
a reaction chamber;
a gas source unit;
a gas supply unit to supply a gas to the reaction chamber;
a substrate supporting unit to support a substrate, the substrate supporting unit being configured to face the gas supply unit; and
a power supply unit comprising a power source to apply a power to the reaction chamber, wherein the gas source unit comprises a first silicon source and a hydrogen source, the first silicon source comprising an acetoxy group; and
wherein the acetoxy group and the hydrogen source react to form a silicon oxycarbonate (SiOC) film on the substrate.
